(19) United States
(12) Patent Application Publication
(10) Pub. No.: US 2025/0079287 A1
(43) Pub. Date: Mar. 6, 2025

(54) SEMICONDUCTOR PACKAGES

(71) Applicant: Samsung Electronics Co., Ltd., Suwon-si (KR)

(72) Inventor: JUNGHOON KANG, Suwon-si (KR)

(21) Appl. No.: 18/744,813

(22) Filed: Jun. 17, 2024

(30) Foreign Application Priority Data
Aug. 31, 2023 (KR) 10-2023-0115234

(51) Int. Cl. H01L 23/498; H01L 23/00; H01L 23/29; H01L 23/538; H01L 25/18

(52) U.S. Cl. CPC H01L 23/49838; H01L 23/29; H01L 23/49866; H01L 23/5386; H01L 24/08; H01L 24/48; H01L 25/18; H01L 2224/08225; H01L 2224/48225; H01L 2924/1815

(57) ABSTRACT

A semiconductor package may include a redistribution substrate that includes a redistribution pattern and a redistribution insulating layer; a semiconductor chip on the redistribution substrate; a connection structure that is spaced apart from the semiconductor chip; and a hybrid via on the connection structure, wherein the hybrid via comprises an inclined portion and an extended portion on the inclined portion, and wherein an angle between the inclined portion and an upper surface of the connection structure ranges from 50° to 75°.

### CROSS-REFERENCE TO RELATED APPLICATIONS

This U.S. non-provisional patent application claims priority under 35 U.S.C. § 119 to Korean Patent Application No. 10-2023-0115234, filed on Aug. 31, 2023, in the Korean Intellectual Property Office, the entire contents of which are hereby incorporated by reference.

### BACKGROUND OF THE INVENTION

The present disclosure relates to semiconductor packages including a via structure with an inclined portion.

A semiconductor package may be configured to enable an integrated-circuit chip as a part of an electronic product. In general, the semiconductor package may include a printed circuit board (PCB) and a semiconductor chip, which is mounted on the PCB and is electrically connected to the PCB using, for example, bonding wires or bumps. As the electronics industry advances, various studies are being conducted to develop a highly reliable, highly integrated, and compact semiconductor package.

### SUMMARY

Some embodiments of the inventive concepts of the present disclosures may provide a semiconductor package with improved reliability and accuracy.

According to some embodiments of the inventive concepts of the present disclosures, a semiconductor package may include a redistribution substrate that includes a redistribution pattern and a redistribution insulating layer; a semiconductor chip on the redistribution substrate; a connection structure that is spaced apart from the semiconductor chip; and a hybrid via on the connection structure, wherein the hybrid via comprises an inclined portion and an extended portion on the inclined portion, and wherein an angle between the inclined portion and an upper surface of the connection structure ranges from 50° to 75°.

According to some embodiments of the inventive concepts of the present disclosures, a semiconductor package may include a redistribution substrate that includes a redistribution pattern and a redistribution insulating layer; a semiconductor chip on the redistribution substrate; a connection structure that is spaced apart from the semiconductor chip; and a hybrid via on the connection structure, wherein the hybrid via comprises an inclined portion and an extended portion on the inclined portion, wherein a width of the inclined portion in a first direction decreases as a distance to the connection structure in a second direction decreases, and wherein the first direction is parallel with an upper surface of the redistribution substrate, and the second direction is perpendicular to the upper surface of the redistribution substrate.

According to some embodiments of the inventive concepts of the present disclosures, a redistribution substrate that includes a redistribution pattern and a redistribution insulating layer; a semiconductor chip on the redistribution substrate; a connection structure that is spaced apart from the semiconductor chip; a hybrid via on the connection structure; a solder via on a lower surface of the redistribution substrate; and a solder pad on a lower surface of the solder via, wherein the hybrid via comprises an inclined portion and an extended portion on the inclined portion, wherein the connection structure comprises a connection mold layer and a penetration connecting portion that is electrically connected to the redistribution pattern, wherein the penetration connecting portion extends into the connection mold layer, wherein the connection mold layer is spaced apart from the semiconductor chip, wherein an angle between the inclined portion of the hybrid via and an upper surface of the penetration connecting portion ranges from 50° to 75°, and wherein the solder pad, the solder via, the penetration connecting portion, and the hybrid via are electrically connected to each other.

### BRIEF DESCRIPTION OF THE DRAWINGS

FIG. 1 is a plan view illustrating a semiconductor package according to some embodiments of the inventive concepts of the present disclosures.

FIG. 2 is a sectional view illustrating a semiconductor package according to some embodiments of the inventive concepts of the present disclosures.

FIG. 3 is an enlarged sectional view illustrating a portion ‘M’ of FIG. 2.

FIGS. 4, 5, 6, 7, 8, 9, 10, 11A, 12A, 13, and 14 are sectional views illustrating a method of fabricating a semiconductor package, according to some embodiments of the inventive concepts of the present disclosures.

FIG. 11B is an enlarged sectional view illustrating a portion ‘N’ of FIG. 11A.

FIG. 12B is an enlarged sectional view illustrating a portion ‘Q’ of FIG. 12A.

FIG. 15 is a sectional view illustrating a semiconductor package according to some embodiments of the inventive concepts of the present disclosures.

FIG. 16 is a sectional view illustrating a semiconductor package according to some embodiments of the inventive concepts of the present disclosures.

### DETAILED DESCRIPTION

Example embodiments of the inventive concepts of the present disclosures will now be described more fully with reference to the accompanying drawings, in which example embodiments are shown. Like reference numerals in the drawings denote like elements, and thus their description may be omitted.

It will be understood that, although the terms “first”, “second”, “third”, and so on may be used herein to illustrate various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the scope of the present disclosure.

It will be understood that when an element or layer is referred to as being “connected to”, or “coupled to” another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is disposed “directly on” or “directly on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is disposed “directly below” or “directly under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, “next”, etc., another event may occur therebetween unless “directly after”, “directly subsequent”, “directly before” or “directly next” is not indicated.

Spatially relative terms, such as “beneath,” “below,” “lower,” “under,” “above,” “upper,” and the like, may be used herein for ease of explanation to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

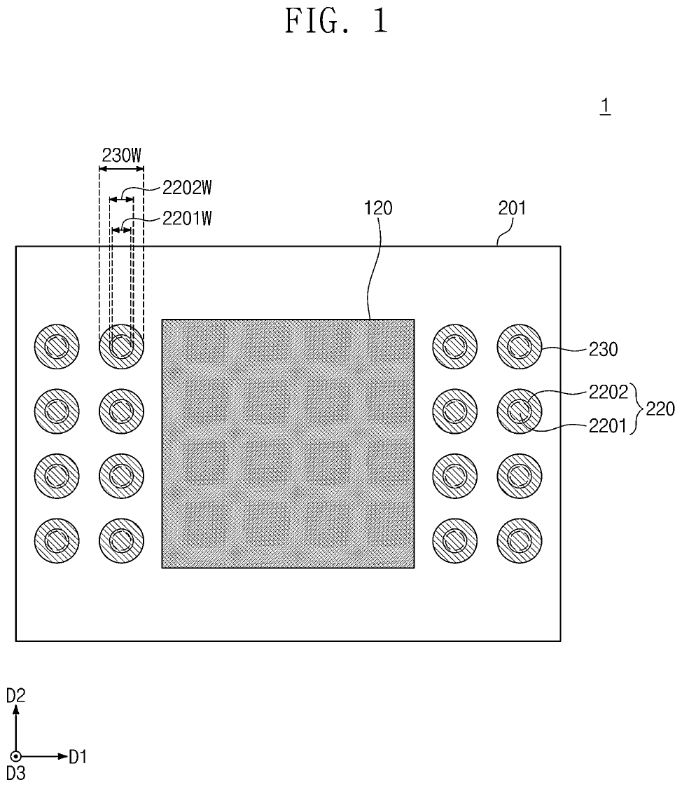

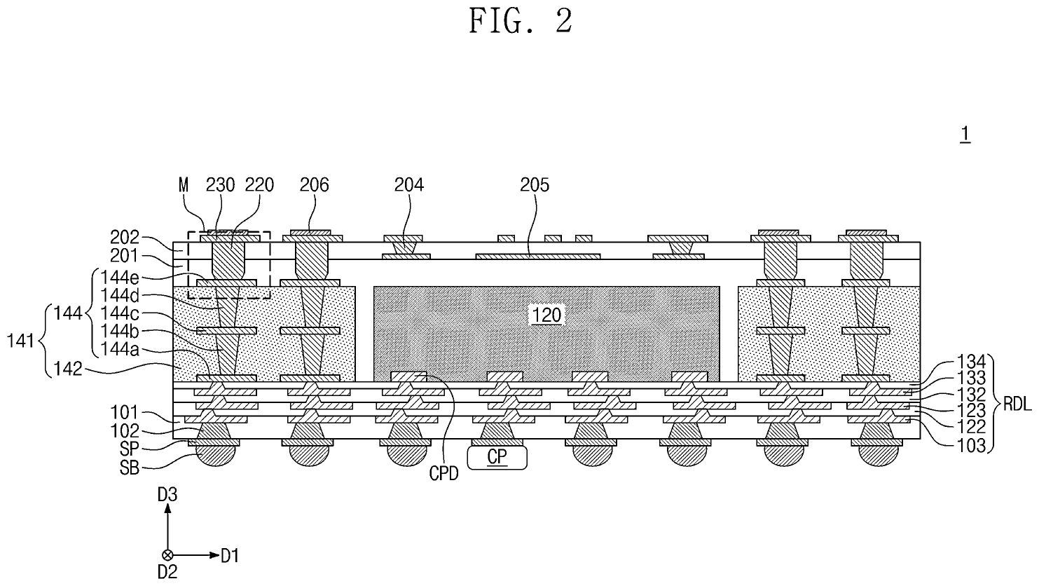

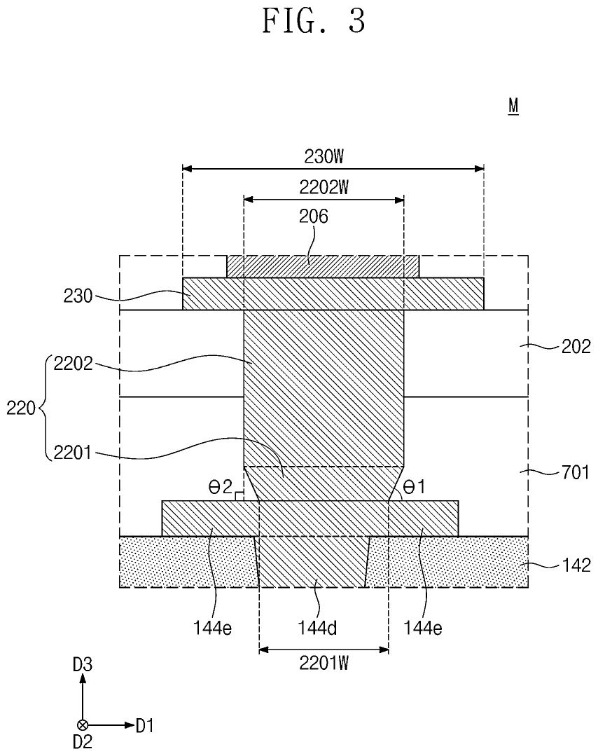

FIG. 1 is a plan view illustrating a semiconductor package according to some embodiments of the inventive concepts of the present disclosures. FIG. 2 is a sectional view illustrating a semiconductor package according to some embodiments of the inventive concepts of the present disclosures. FIG. 3 is an enlarged sectional view illustrating a portion ‘M’ of FIG. 2.

Referring to FIGS. 1 to 3, a semiconductor package 1 may include a solder ball SB, a passive device CP spaced apart from the solder ball SB, a solder pad SP on the solder ball SB, a solder via 102 on the solder pad SP, a solder insulating layer 101 extending around (e.g., enclosing or surrounding) the solder via 102, a redistribution substrate RDL on the solder via 102 and/or on (or in) the solder insulating layer 101, a connection structure 141 on the redistribution substrate RDL, a semiconductor chip 120 on the redistribution substrate RDL, a chip pad CPD in the semiconductor chip 120, a hybrid via 220 on the connection structure 141, an upper pad 230 on the hybrid via 220, a conductive pad 206 on the upper pad 230, a chip mold layer 201 on the redistribution substrate RDL, an interconnection pad 205 on the chip mold layer 201, an interconnection via 204 on the interconnection pad 205, and a capping mold layer 202 on the chip mold layer 201. As used herein, the term “and/or” includes any and all combinations of one or more of the associated listed items.

The solder ball SB may be provided. The solder pad SP may be provided on the solder ball SB. The solder ball SB may be formed of or include at least one of solder materials (e.g., tin, lead, silver, and alloys thereof). The solder ball SB may include a signal solder ball, a ground solder ball, and/or a power solder ball.

The solder pad SP may be provided on the solder ball SB. The solder pad SP may include a conductive material. The solder via 102 may be provided on the solder pad SP. The solder via 102 may include a conductive material. The solder via 102, the solder pad SP, and the solder ball SB may be electrically connected to each other.

The passive device CP may be provided. The passive device CP may be provided below the solder pad SP. The passive device CP may be adjacent the solder ball SB. The passive device CP may be disposed between a plurality of solder balls SB. The passive device CP may include, for example, a capacitor, a diode, a photodiode, and/or a resistor.

The solder insulating layer 101 may be provided on the solder pad SP. The solder insulating layer 101 may be on a side surface of the solder via 102. For example, the solder insulating layer 101 may be provided to extend around (e.g., enclose or surround) a side surface of the solder via 102. The solder insulating layer 101 may include an insulating material. The solder insulating layer 101 may include a non-photoimageable material. The solder insulating layer 101 may be, for example, an ABF film. The solder insulating layer 101 may contain an impurity. The solder insulating layer 101 may include, for example, a filler grain.

The redistribution substrate RDL may be provided on the solder pad SP and the solder insulating layer 101. The redistribution substrate RDL may include redistribution patterns 103, 123, and 133 and redistribution insulating layers 122, 132, and 134. The redistribution substrate RDL may include a plate-shaped structure (e.g., redistribution patterns 103, 123, and 133 and/or redistribution insulating layers 122, 132, and 134) that is extended in a first direction D1 and a second direction D2.

The redistribution patterns 103, 123, and 133 may include a first redistribution pattern 103 on the solder via 102, a second redistribution pattern 123 on the first redistribution pattern 103, and a third redistribution pattern 133 on the second redistribution pattern 123. In this case, the redistribution patterns 103, 123, and 133 may include a lower portion, which is extended in the first direction D1 (and/or the second direction D2), and an upper portion, which protrudes from the lower portion in a third direction D3.

The solder via 102, the first redistribution pattern 103, the second redistribution pattern 123, and the third redistribution pattern 133 may be electrically connected to each other.

The redistribution insulating layers 122, 132, and 134 may include a first redistribution insulating layer 122 on the solder insulating layer 101, a second redistribution insulating layer 132 on the first redistribution insulating layer 122, and a third redistribution insulating layer 134 on the second redistribution insulating layer 132.

The first redistribution insulating layer 122 may include an organic material (e.g., a photoimageable dielectric (PID) material). The PID material may be a polymeric material. The PID material may include, for example, photo-imageable polyimide, polybenzoxazole, phenol-based polymers, and/or benzocyclobutene-based polymers.

In some embodiments, a portion of the redistribution substrate RDL may be disposed in the solder insulating layer 101. For example, the first redistribution pattern 103 may be provided in the solder insulating layer 101 and the first redistribution insulating layer 122. The first redistribution pattern 103 may include a conductive material. The first redistribution pattern 103 may be in contact with the solder insulating layer 101, the solder via 102, and the first redistribution insulating layer 122.

The first direction D1 may be parallel to an upper surface of the redistribution substrate RDL. The second direction D2 may be parallel to the upper surface of the redistribution substrate RDL and may be substantially perpendicular to the first direction D1. The first direction D1 may not be parallel to the second direction D2. The third direction D3 may be substantially perpendicular to the upper surface of the redistribution substrate RDL. The first direction D1 and the second direction D2 may be referred to as horizontal directions. The third direction D3 may be referred to as a vertical direction.

The second redistribution pattern 123 may be disposed in the first redistribution insulating layer 122 and the second redistribution insulating layer 132.

Each of the second and third redistribution insulating layers 132 and 134 may be provided to have substantially the same features as the first redistribution insulating layer 122. Each of the second and third redistribution patterns 123 and the 133 may also be provided to have substantially the same features as the first redistribution pattern 103.

The connection structure 141 may be disposed on the redistribution substrate RDL. The connection structure 141 may include a penetration connecting portion 144, which is electrically connected to the redistribution patterns 103, 123, and 133, and a connection mold layer 142, which is pierced by the penetration connecting portion 144. For example, the penetration connecting portion 144 may extend into (e.g., penetrate) the connection mold. The connection structure 141 may include a plurality of penetration connecting portions 144. In some embodiments, the connection structure 141 may include a PCB substrate.

The connection mold layer 142 may be disposed on the redistribution substrate RDL. The connection mold layer 142 may include an insulating material. The connection mold layer 142 may include a dielectric material. The connection mold layer 142 may be configured to electrically separate the penetration connecting portions 144 from each other.

The penetration connecting portion 144 may include a first connecting portion 144a, a second connecting portion 144b on the first connecting portion 144a, a third connecting portion 144c on the second connecting portion 144b, a fourth connecting portion 144d on the third connecting portion 144c, and a fifth connecting portion 144e on the fourth connecting portion 144d. The first connecting portion 144a, the second connecting portion 144b, the third connecting portion 144c, the fourth connecting portion 144d, and the fifth connecting portion 144e may be continuously connected to each other without any (visually recognizable) interface therebetween, and in this case, the penetration connecting portion 144 may form a single object. The connection mold layer 142 may extend around (e.g., enclose or surround) the first connecting portion 144a, the second connecting portion 144b, the third connecting portion 144c, and the fourth connecting portion 144d of the penetration connecting portion 144.

A width of the first connecting portion 144a (in a horizontal direction) may be greater (larger) than a width of a lower portion of the second connecting portion 144b (in the horizontal direction). A width of an upper portion of the second connecting portion 144b (in the horizontal direction) may be greater (larger) than the width of the lower portion of the second connecting portion 144b (in the horizontal direction). The width of the second connecting portion 144b (in the horizontal direction) may decrease from the upper portion of the second connecting portion 144b to the lower portion of the second connecting portion 144b. The width of the upper portion of the second connecting portion 144b (in the horizontal direction) may be lesser (smaller) than a width of the third connecting portion 144c (in the horizontal direction). A width of an upper portion of the fourth connecting portion 144d (in the horizontal direction) may be greater (larger) than a width of a lower portion of the fourth connecting portion 144d (in the horizontal direction). The width of the fourth connecting portion 144d (in the horizontal direction) may decrease from the upper portion of the fourth connecting portion 144d to the lower portion of the fourth connecting portion 144d. The width of the upper portion of the fourth connecting portion 144d (in the horizontal direction) may be lesser (smaller) than a width of the fifth connecting portion 144e (in the horizontal direction). Herein, the terms for relative locations may refer to a distance from the upper surface of the redistribution substrate RDL in the vertical direction. For example, a higher portion of element A is farther than a lower portion of element A from the upper surface of the redistribution substrate RDL in the third direction D3.

The first connecting portion 144a, the second connecting portion 144b, the third connecting portion 144c, and the fourth connecting portion 144d may be provided to extend in (e.g., penetrate) the connection mold layer 142. Since the first connecting portion 144a, the second connecting portion 144b, the third connecting portion 144c, and the fourth connecting portion 144d are provided to penetrate the connection mold layer 142, the first connecting portion to fourth connecting portion 144a, 144b, 144c, and 144d may be (at least partially) enclosed by the same insulating material. The number and structure of connecting portions (e.g., the first, second, third, fourth, and fifth connecting portions 144a, 144b, 144c, 144d, and 144e) of the penetration connecting portion 144 are not limited to the embodiments disclosed above.

The chip pad CPD may be disposed on the redistribution substrate RDL (e.g., third redistribution pattern 133). The chip pad CPD may be disposed in the semiconductor chip 120. The chip pad CPD may include a plurality of chip pads CPD. The chip pad CPD may be formed of or include a conductive material.

The semiconductor chip 120 may be disposed on the redistribution substrate RDL. The connection mold layer 142 and the semiconductor chip 120 may be spaced apart from each other. The semiconductor chip 120 may be disposed between the connection structures 141. The semiconductor chip 120 may be electrically connected to the redistribution substrate RDL (e.g., third redistribution pattern 133) through the chip pad CPD.

The chip mold layer 201 may be provided to extend around (e.g., enclose or surround) the connection structure 141 and the semiconductor chip 120. The chip mold layer 201 may be provided on the redistribution substrate RDL. The chip mold layer 201 may be on (e.g., in contact with) a side surface of the hybrid via 220. The chip mold layer 201 may include an insulating material. The chip mold layer 201 may include a non-photoimageable material.

The capping mold layer 202 may be disposed on the chip mold layer 201. The capping mold layer 202 may include an insulating material. The capping mold layer 202 may include a non-photoimageable material. The capping mold layer 202 may be on (e.g., in contact with) the side surface of the hybrid via 220.

The interconnection pad 205 may be disposed on the chip mold layer 201. The interconnection pad 205 may be overlapped (in the third direction D3) with the semiconductor chip 120. The interconnection pad 205 may include a conductive material. A level of a lower surface of the interconnection pad 205 may be higher than a level of a lower surface of the hybrid via 220 and may be lower than a level of an upper surface of the hybrid via 220. The interconnection pad 205 may be disposed in the capping mold layer 202.

The interconnection via 204 may be disposed on the interconnection pad 205. The interconnection via 204 may include a conductive material. The interconnection via 204 may be disposed in the capping mold layer 202. The interconnection via 204 may be overlapped (in the third direction D3) with the semiconductor chip 120.

The hybrid via 220 may be disposed on the connection structure 141. The hybrid via 220 may be disposed to be in direct contact with the penetration connecting portion 144 (e.g., fifth connecting portion 144e). The side surface of the hybrid via 220 may be on (e.g., in contact with) the chip mold layer 201 and the capping mold layer 202. The hybrid via 220 may be provided to extend in (e.g., penetrate) the capping mold layer 202 and may be extended into the chip mold layer 201. The penetration connecting portion 144 of the connection structure 141 may electrically connect the hybrid via 220 to the redistribution substrate RDL. The hybrid via 220 may include a conductive material.

The upper pad 230 may be disposed on the interconnection via 204 and the hybrid via 220. The conductive pad 206 may be disposed on the upper pad 230. The upper pad 230 may include a conductive material. The conductive pad 206 may include a conductive material. The conductive pad 206 may be a plurality of conductive pads (a plurality of conductive layers) 206. The conductive pad 206 may be formed of or include for example, Ni and/or Au. The conductive pad 206 may be electrically connected to the upper pad 230, the hybrid via 220, and the penetration connecting portion 144. The upper pad 230 may be electrically connected to the interconnection via 204 and the interconnection pad 205.

The hybrid via 220 may include an inclined portion 2201, which is in direct contact with the penetration connecting portion 144 (e.g., the fifth connecting portion 144e), and an extended portion 2202, which is provided on the inclined portion 2201. The inclined portion 2201 and the extended portion 2202 may form a single object which is continuously extended without any (visually recognizable) interface therein. The inclined portion 2201 may be disposed in the chip mold layer 201. The extended portion 2202 may be disposed in the capping mold layer 202 and/or the chip mold layer 201. The extended portion 2202 may be in direct contact with the upper pad 230. The extended portion 2202 may be extended from the inclined portion 2201 in a direction perpendicular to the redistribution substrate RDL (e.g., in the third direction D3). A width of the inclined portion 2201 (e.g., in the first direction D1 and/or the second direction D2) may decrease as a distance to the connection structure 141 decreases (e.g., the penetration connecting portion 144).

An angle between the inclined portion 2201 and the uppermost surface of the connection structure 141 may be defined as a first angle θ1. In other words, the first angle θ1 may refer to the angle between the inclined portion 2201 and the uppermost surface of the penetration connecting portion 144 (e.g., the angle between the inclined portion 2201 and the uppermost (upper) surface of the fifth connecting portion 144e). The first angle θ1 may range from 50° to 75°.

An angle between a side surface of an extended portion 2202 and the uppermost surface of the connection structure 141 may be defined as a second angle θ2. In other words, the second angle θ2 may refer to the angle between the extended portion 2202 and the uppermost surface of the penetration connecting portion 144 (e.g., the angle between the extended portion 2202 and the uppermost (upper) surface of the fifth connecting portion 144e). The first angle θ1 may be smaller than the second angle θ2.

A width 2202W of the extended portion 2202 (in the first direction D1 and/or the second direction D2) may be greater (larger) than a width 2201W of the lowermost surface of the inclined portion 2201 (in the first direction D1 and/or the second direction D2, respectively). The width of the inclined portion 2201 (in the first direction D1 and/or the second direction D2) may decrease as a distance from the extended portion 2202 increases. A width 230W of the upper pad 230 (in the first direction D1 and/or the second direction D2) may be greater (larger) than the width 2202W of the extended portion 2202 (in the first direction D1 and/or the second direction D2, respectively). A width of the uppermost surface of the penetration connecting portion 144 (in the first direction D1 and/or the second direction D2) may be greater (larger) than the width 2202W of the extended portion 2202 (in the first direction D1 and/or the second direction D2, respectively). In some embodiments, the width 2202W of the extended portion 2202 (in the first direction D1 and/or the second direction D2) may be uniform.

Since the width 2201W of the inclined portion 2201 of the hybrid via 220 (in the first direction D1 and/or the second direction D2) decreases as a distance from the extended portion 2202 increases or a distance to the connection structure 141 decreases, a void may not be formed (or may be reduced) in the hybrid via 220.

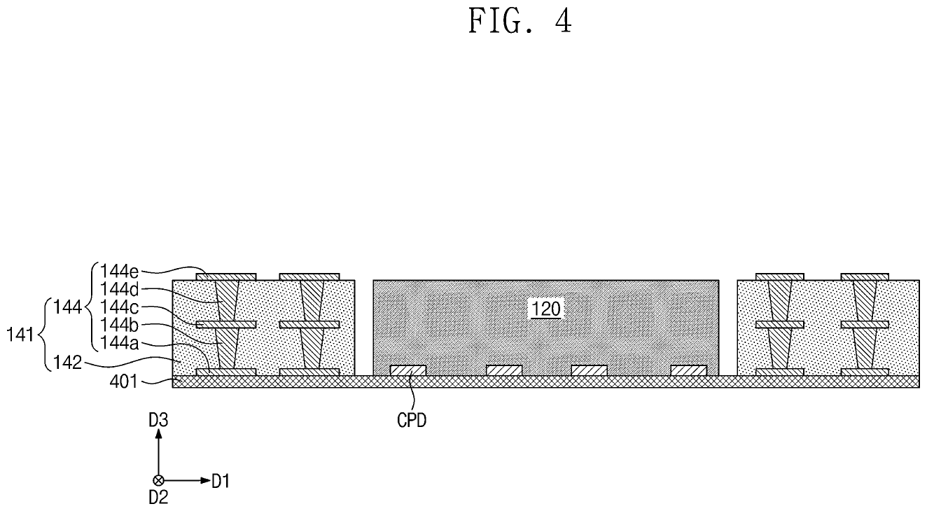

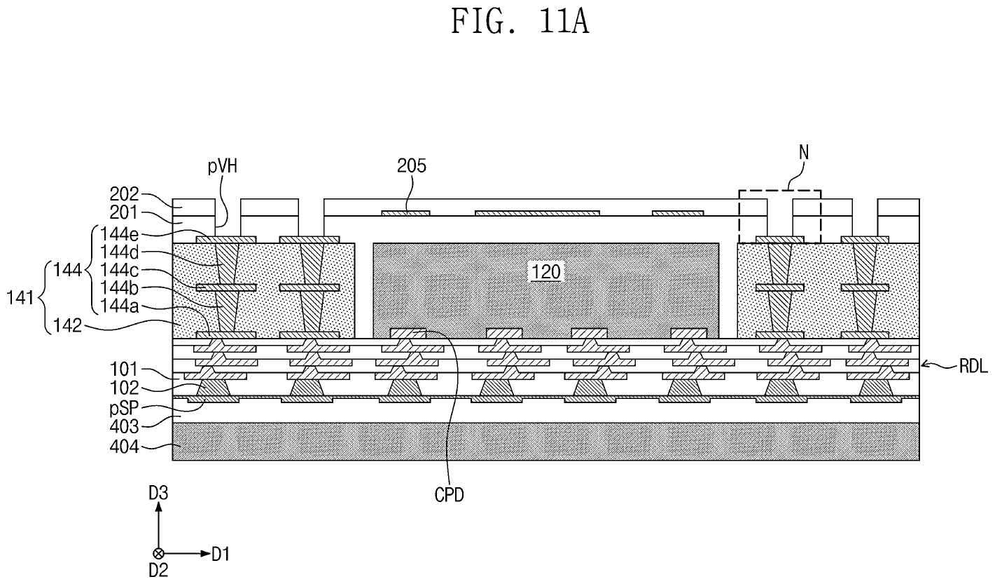

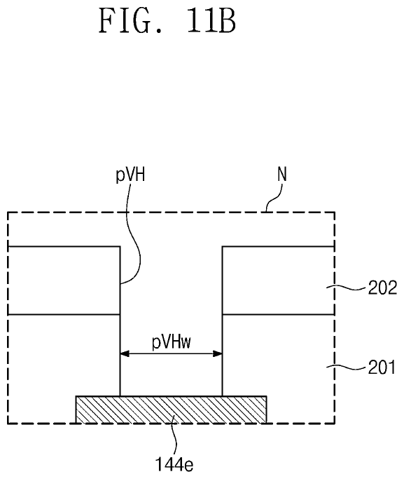

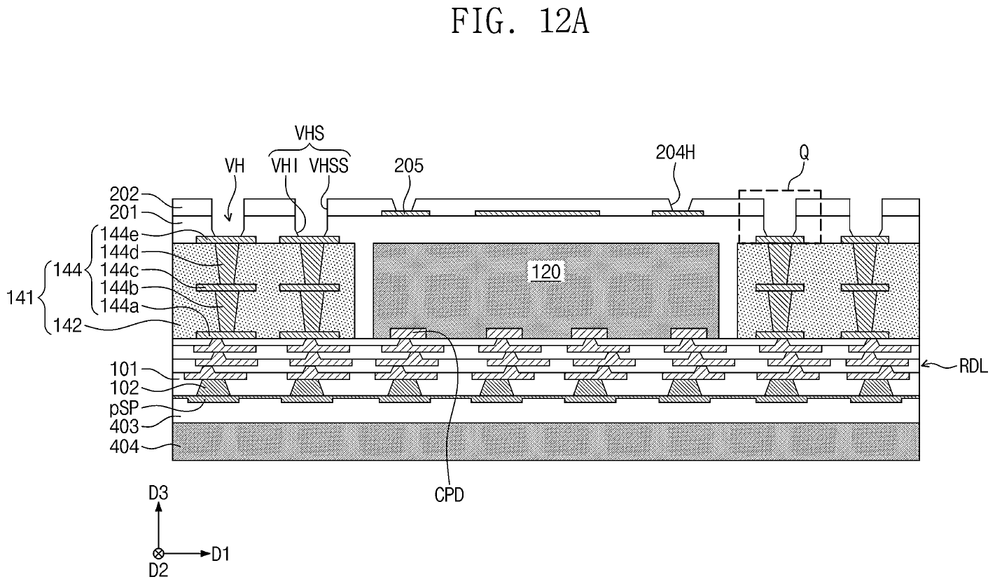

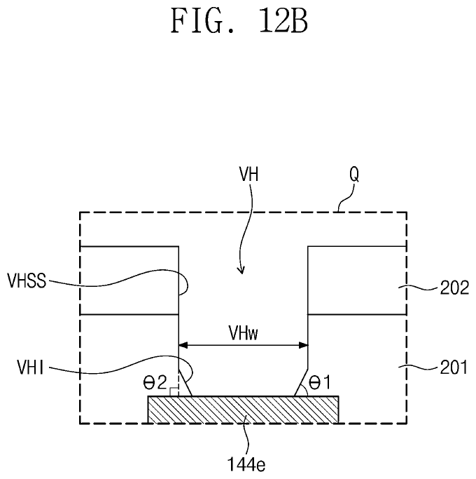

FIGS. 4, 5, 6, 7, 8, 9, 10, 11A, 12A, 13, and 14 are sectional views illustrating a method of fabricating a semiconductor package, according to some embodiments of the inventive concepts of the present disclosures. FIG. 11B is an enlarged sectional view illustrating a portion ‘N’ of FIG. 11A. FIG. 12B is an enlarged sectional view illustrating a portion ‘Q’ of FIG. 12A.

Referring to FIG. 4, a die film 401 may be provided. The connection structure 141 may be disposed on the die film 401. The connection structure 141 may be attached to the die film 401. The connection structure 141, which includes the connection mold layer 142 and the penetration connecting portion 144 (at least partially) (buried) therein, may be disposed on the die film 401. In some embodiments, a plurality of connection structures 141 may be provided on the die film 401. The semiconductor chip 120 may be adjacent the connection structure 141. The semiconductor chip 120 may be placed between the connection structures 141 to be spaced apart from the connection structures 141. The semiconductor chip 120 may be attached to the die film 401. The semiconductor chip 120 may include the chip pad CPD.

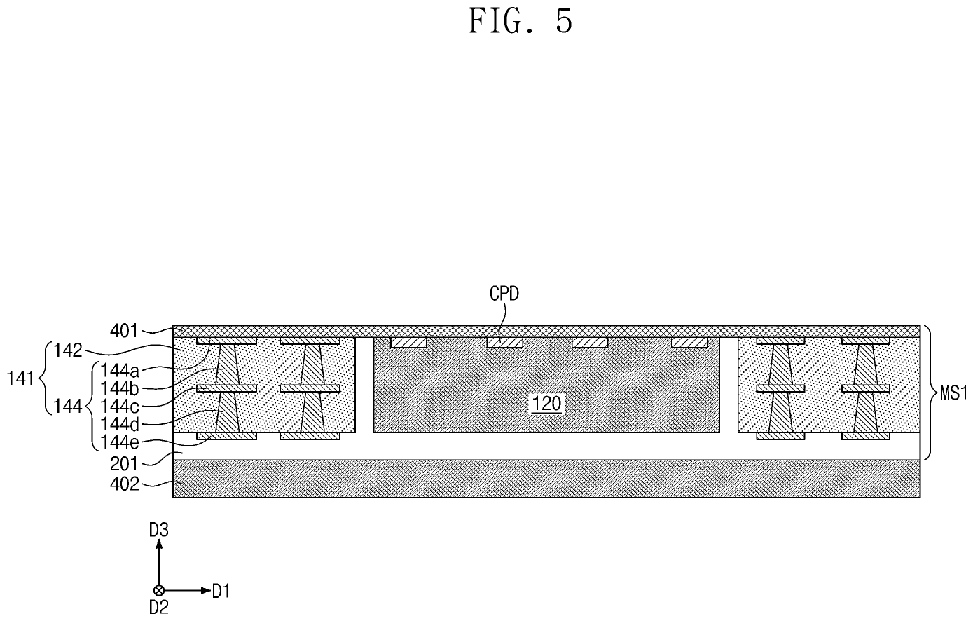

Referring to FIG. 5, the chip mold layer 201 may be formed on the connection structures 141 and the semiconductor chip 120. The formation of the chip mold layer 201 may include forming the chip mold layer 201 to overlap (e.g., cover) the connection structures 141 and the semiconductor chip 120. The chip mold layer 201 may be on the die film 401. For example, the connection structure 141, the semiconductor chip 120, and the chip mold layer 201 may be on a same side of the die film 401.

After the formation of the chip mold layer 201, the chip mold layer 201 may be placed on and attached to a first carrier 402. A first middle structure MS1 may include the die film 401, the connection structures 141, the chip pad CPD, the semiconductor chip 120, and the chip mold layer 201. In some embodiments, the die film 401, the connection structures 141, the chip pad CPD, the semiconductor chip 120, and the chip mold layer 201 may constitute the first middle structure MS1. The first middle structure MS1 may be inverted and then may be attached to the first carrier 402.

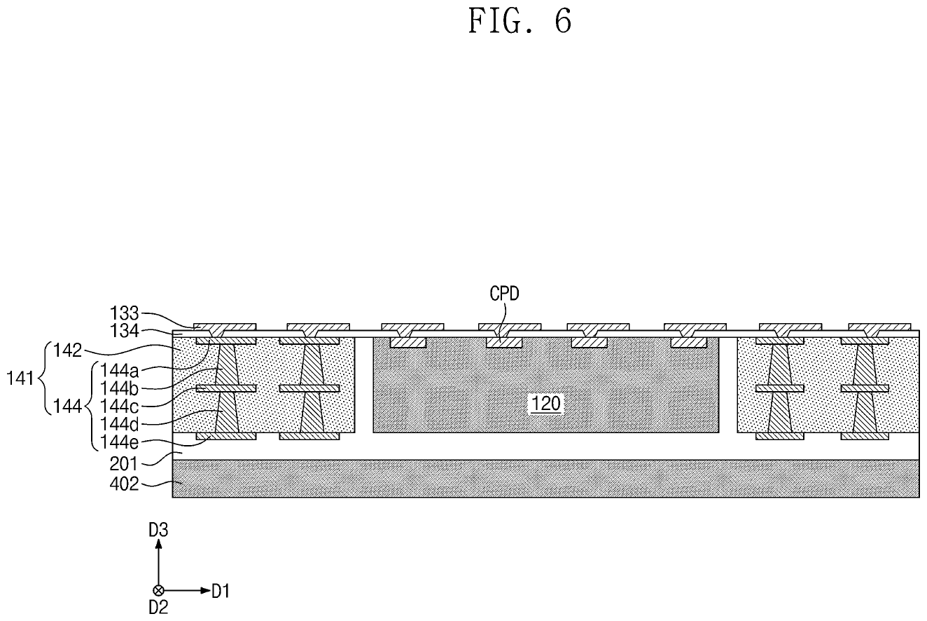

Referring to FIG. 6, the die film 401 may be removed. For example, the first middle structure MS1 of FIG. 5 may be inverted and may be disposed on (e.g., fastened to or attached to) the first carrier 402 substrate, and then, the die film 401 may be removed. Next, the third redistribution insulating layer 134 and the third redistribution pattern 133 may be formed. The formation of the third redistribution insulating layer 134 and the third redistribution pattern 133 may include performing a removal (e.g., a grinding) process on the chip mold layer 201 to expose an upper surface of the connection structure 141 (e.g., an upper surface of the first connecting portion 144a in FIG. 6) and an upper surface of the chip pad CPD, forming the third redistribution insulating layer 134 on the exposed upper surface of the connection structure 141, the exposed upper surface of the chip pad CPD, and an upper surface of the chip mold layer 201, patterning the third redistribution insulating layer 134, and forming the third redistribution pattern 133 using a plating process. The forming of the third redistribution insulating layer 134 may include forming a photoimageable material on the upper surface of the chip mold layer 201. In some embodiments, the formation of the third redistribution pattern 133 using the plating process may include forming a seed metal layer, which contains a conductive material, on the patterned structure of the third redistribution insulating layer 134, forming a metal layer through a plating process using the seed metal layer as a seed layer, patterning the metal layer to form the third redistribution pattern 133, and then, removing the seed metal layer.

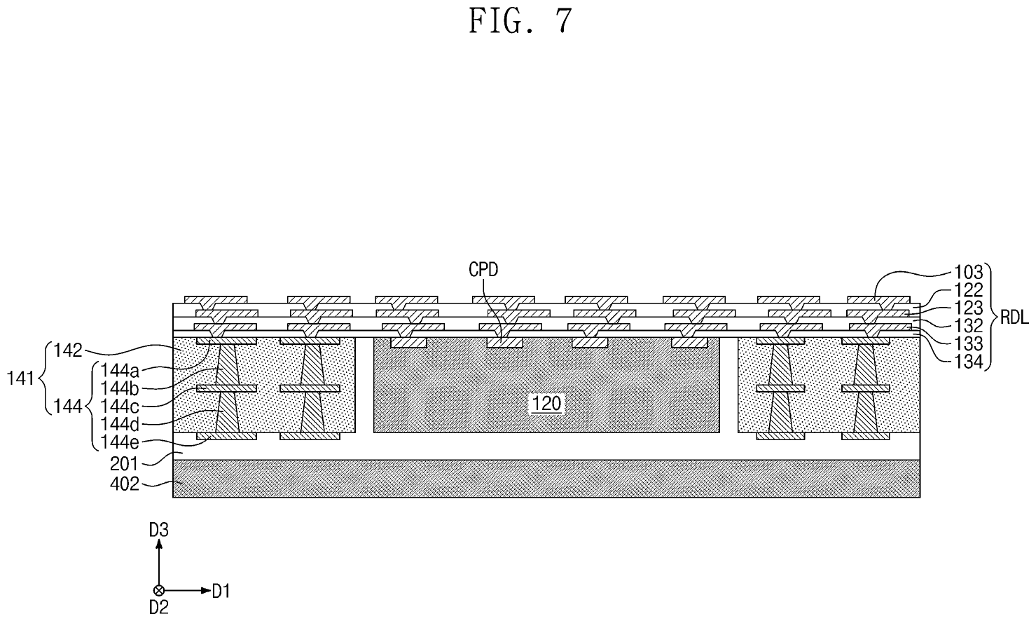

Referring to FIG. 7, the second redistribution insulating layer 132 and the second redistribution pattern 123 may be formed on the third redistribution insulating layer 134 and the third redistribution pattern 133. The formation of the second redistribution insulating layer 132 may include forming a photoimageable (insulating) material on (e.g., to cover or to overlap) the third redistribution insulating layer 134 and an upper surface of the third redistribution pattern 133. The formation of the second redistribution pattern 123 may include patterning the second redistribution insulating layer 132 and performing a plating process to form the second redistribution pattern 123.

The first redistribution insulating layer 122 and the first redistribution pattern 103 may be formed on the second redistribution insulating layer 132 and the second redistribution pattern 123. The first redistribution insulating layer 122 and the first redistribution pattern 103 may be formed by a method that is similar to that for the second redistribution insulating layer 132 and the second redistribution pattern 123. As a result of the formation of the first redistribution insulating layer 122 and the first redistribution pattern 103, the redistribution substrate RDL may be formed. However, the number and structure of the redistribution insulating layers and the redistribution insulating layers of the redistribution substrate RDL are not limited to the embodiments described above.

The penetration connecting portion 144 may be electrically connected to the third redistribution pattern 133, the second redistribution pattern 123, and the first redistribution pattern 103. The chip pad CPD may be electrically connected to the third redistribution pattern 133, the second redistribution pattern 123, and the first redistribution pattern 103. The redistribution substrate RDL may be electrically connected to the semiconductor chip 120 through the chip pad CPD.

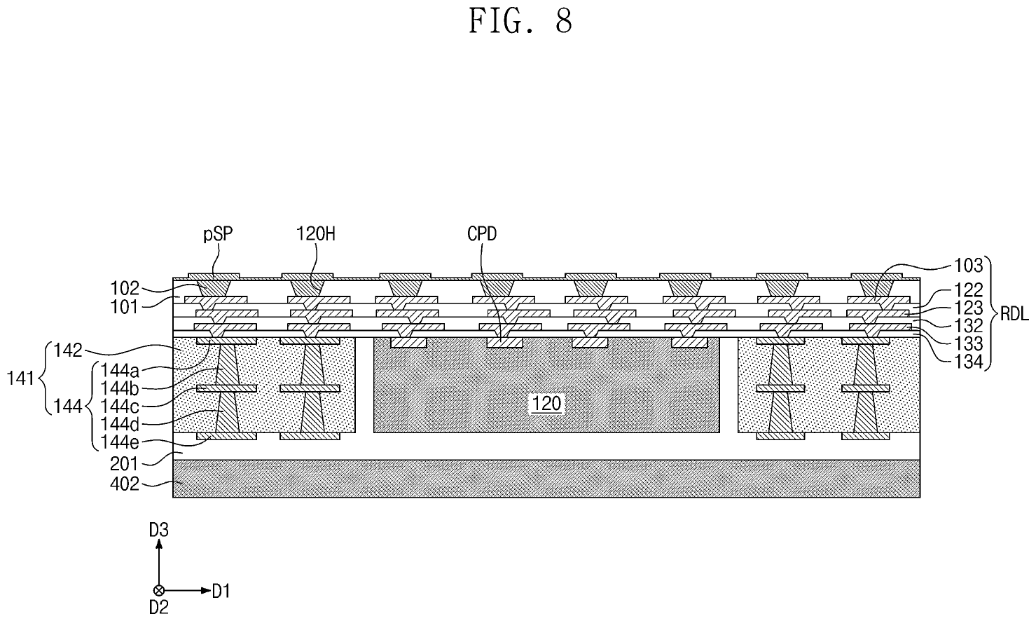

Referring to FIG. 8, the solder insulating layer 101 may be formed on the redistribution substrate RDL (e.g., on the first redistribution pattern 103 and/or the first redistribution insulating layer 122). The solder via 102 may be formed on the first redistribution pattern 103. The formation of the solder via 102 may include forming a solder via hole 120H in the solder insulating layer 101 to (at least partially) expose the first redistribution pattern 103 and filling the solder via hole 120H with a conductive material. The solder via 102 may be formed as a result of the filling of the solder via hole 120H.

After the formation of the solder via 102, a preliminary solder pad pSP may be formed on the solder via 102. The formation of the preliminary solder pad pSP may include forming a conductive material on the solder via 102. The formation of the preliminary solder pad pSP may include forming a conductive material on the solder via 102. The preliminary solder pad pSP may be formed to be thicker (e.g., thicker in the third direction D3) in a region where the solder pad SP will be formed, than in other regions where the solder pad SP will not be formed. That is, the preliminary solder pad pSP may be formed by forming a conductive material to a larger thickness (e.g., larger thickness in the third direction D3) in the regions where the solder pad SP will be formed, than in the other regions where the solder pad SP will not be formed.

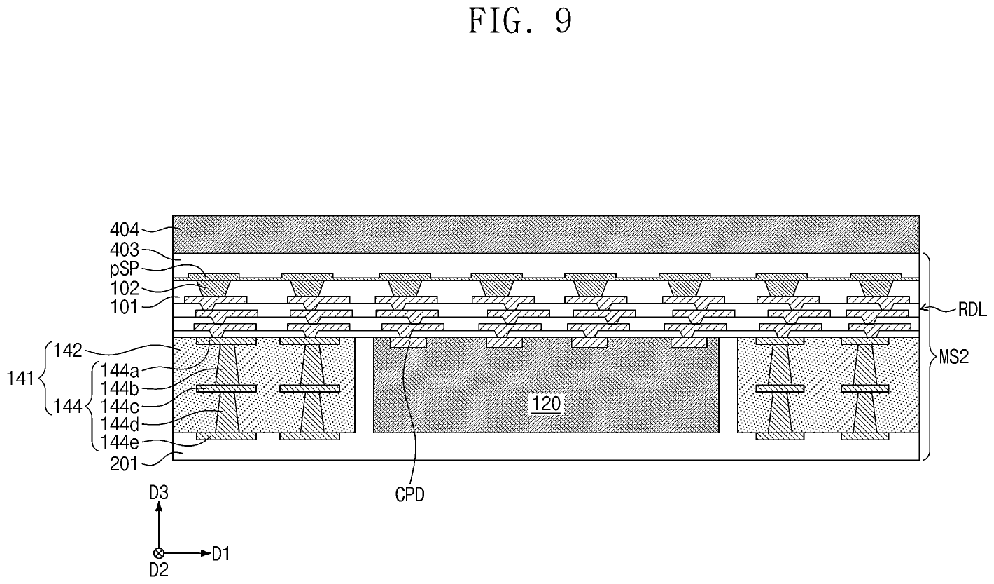

Referring to FIG. 9, the first carrier 402 may be removed. Next, a protection layer 403 may be formed on (e.g., to cover or overlap) the preliminary solder pad pSP. The formation of the protection layer 403 may include forming an insulating material on an upper surface of the preliminary solder pad pSP. A second middle structure MS2 may include the connection structures 141, the chip pad CPD and the semiconductor chip 120, the chip mold layer 201, the redistribution substrate RDL, the solder via 102, the preliminary solder pad pSP, and the protection layer 403. The connection structures 141, the chip pad CPD and the semiconductor chip 120, the chip mold layer 201, the redistribution substrate RDL, the solder via 102, the preliminary solder pad pSP, and the protection layer 403 may constitute the second middle structure MS2. The second middle structure MS2 may be inverted and then may be attached to a second carrier 404.

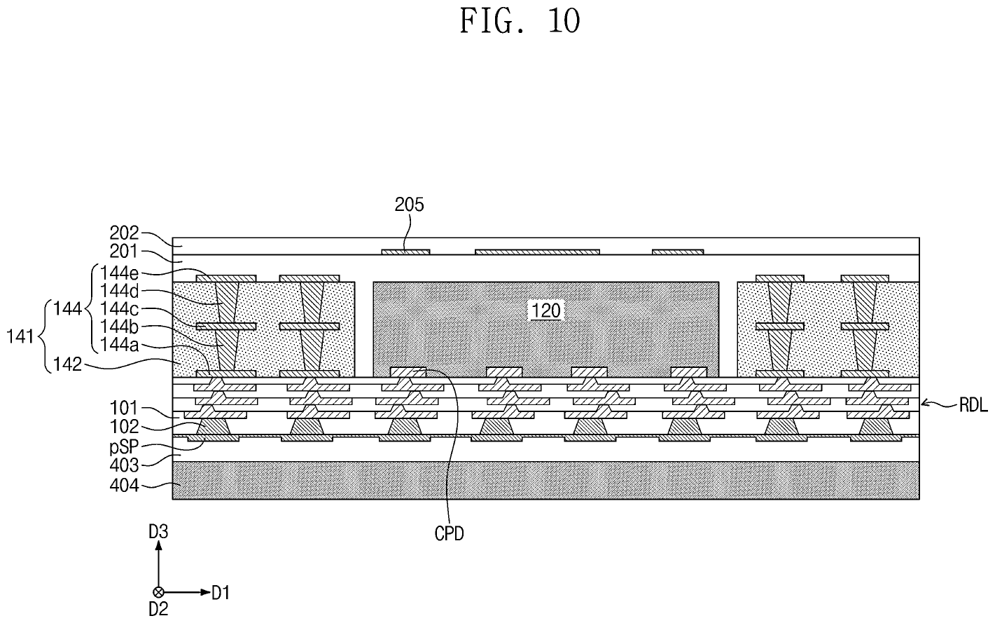

Referring to FIG. 10, the second middle structure MS2 may be attached to the second carrier 404 of FIG. 9 and may be inverted. Next, the interconnection pad 205 and the capping mold layer 202 may be formed on the chip mold layer 201. The interconnection pad 205 may include a conductive material.

The formation of the interconnection pad 205 may include conformally forming a conductive material on the chip mold layer 201 and patterning the conductive material. The formation of the capping mold layer 202 may include depositing a non-photoimageable material on (e.g., to cover or to overlap) the interconnection pad 205 and the upper surface of the chip mold layer 201.

Referring to FIGS. 11A and 11B, a preliminary via hole pVH may be formed. The formation of the preliminary via hole pVH may include at least partially removing (e.g., etching) the chip mold layer 201. The preliminary via hole pVH may be formed to expose at least a portion of an upper surface of the fifth connecting portion 144e of the penetration connecting portion 144. A width pVHw of the preliminary via hole pVH may be constant, regardless of a distance from the fifth connecting portion 144e (in the third direction D3). The width pVHw of the preliminary via hole pVH may refer to a width of the preliminary via hole pVH in the first direction D1 and/or a width of the preliminary via hole pVH in the second direction D2. A side surface of the preliminary via hole pVH may be substantially perpendicular to the upper surface of the redistribution substrate RDL. In some embodiments, the preliminary via hole pVH may be formed by a laser etching process.

Referring to FIGS. 12A and 12B, a hybrid via hole VH may be formed by additionally etching the side surface of the preliminary via hole pVH. In this case, a side surface VHS of the hybrid via hole VH may include an inclined side surface VHI and an extended side surface VHSS. The additional etching of the side surface of the preliminary via hole pVH may include a laser etching step.

An angle between the inclined side surface VHI and the uppermost surface of the connection structure 141 (e.g., the upper surface of the fifth connecting portion 144e) may be defined as a first angle θ1. In other words, the first angle θ1 may refer to the angle between the inclined side surface VHI and the uppermost surface of the penetration connecting portion 144 (e.g., the angle between the inclined side surface VHI and the upper surface of the fifth connecting portion 144e). The first angle θ1 may range from 50° to 75°.

An angle between a side surface of the extended side surface VHSS and the uppermost surface of the connection structure 141 (e.g., the upper surface of the fifth connecting portion 144e) may be defined as a second angle θ2. In other words, the second angle θ2 may refer to the angle between the extended portion 2202 (referring to FIG. 3) and the uppermost surface of the penetration connecting portion 144 (e.g., the angle between the extended portion 2202 and the uppermost surface of the fifth connecting portion 144e). The first angle θ1 may be smaller than the second angle θ2. In some embodiments, the second angle θ2 may be 90°.

The width pVHw of the preliminary via hole pVH (in the first direction D1 and/or the second direction D2) may be smaller than a width VHw of the hybrid via hole VH (in the first direction D1 and/or the second direction D2, respectively). In the hybrid via hole VH, a portion including the extended side surface VHSS may have a constant width regardless of the distance to the uppermost surface of the connection structure 141 (e.g., the upper surface of the fifth connecting portion 144e) in the third direction D3, and a portion including the inclined side surface VHI may have a decreasing width (in the first direction D1 and/or the second direction D2) as a distance to the uppermost surface of the connection structure 141 (e.g., the upper surface of the fifth connecting portion 144e) in the third direction D3 decreases.

An interconnection via hole 204H may be formed on the interconnection pad 205 to be overlapped with the semiconductor chip 120 (in the third direction D3). In some embodiments, the interconnection via hole 204H may be formed by a laser etching process.

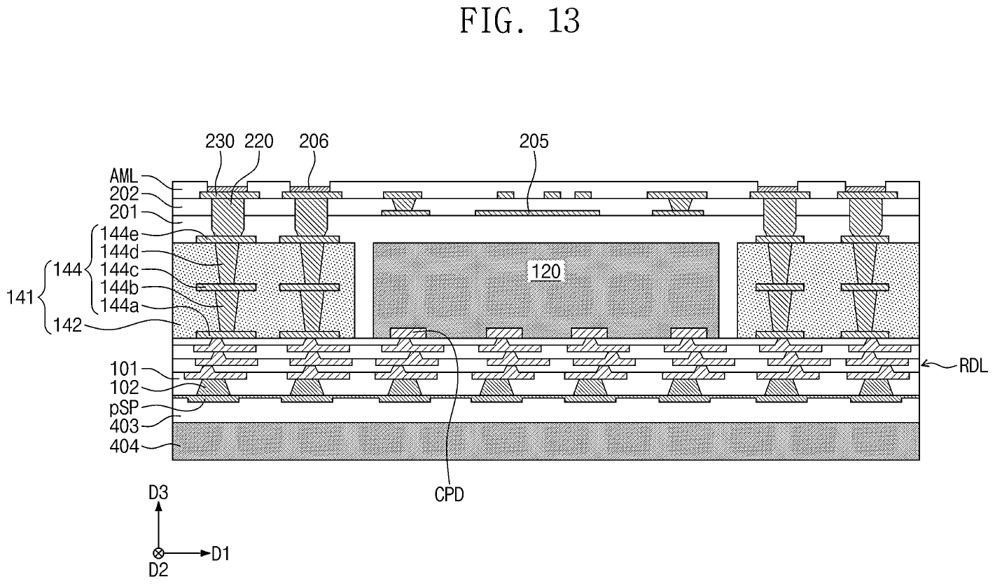

Referring to FIG. 13, the hybrid via hole VH and the interconnection via hole 204H may be filled with a conductive material. The conductive material may include, for example, copper.

Thereafter, a seed conductive material (not shown) may be formed on the capping mold layer 202 and then may be etched to form the upper pad 230. An additional molding layer AML may be formed on the upper pad 230 (and the capping mold layer 202). The formation of the additional molding layer AML may include forming an insulating material on (e.g., to cover or to overlap) the upper surface of the capping mold layer 202 and the upper surface of the upper pad 230. After the formation of the additional molding layer AML, the additional molding layer AML may be patterned.

An upper surface of the upper pad 230 may be (at least partially) exposed to the outside, as a result of the patterning of the additional molding layer AML. Next, a conductive material may be formed on the exposed surface of the upper pad 230. As a result, the conductive pad 206 may be formed. In the case where a plurality of conductive layers are formed, the conductive pad 206 may include a plurality of conductive layers. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

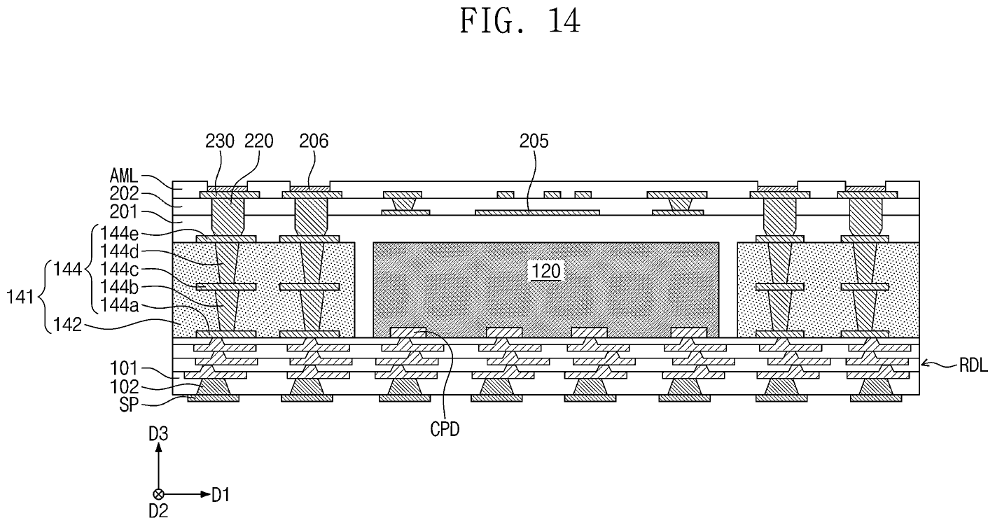

Referring to FIG. 14, the protection layer 403 and the second carrier 404 may be removed. Thereafter, a portion of the preliminary solder pad pSP may be etched to form the solder pad SP. Since the solder pad SP is formed by etching the portion of the preliminary solder pad pSP, the solder pads SP may be spaced apart from each other.

Referring back to FIG. 2, the additional molding layer AML may be removed, and the solder ball SB may be attached to the solder pad SP. The passive device CP may be attached to at least one of the solder pads SP.

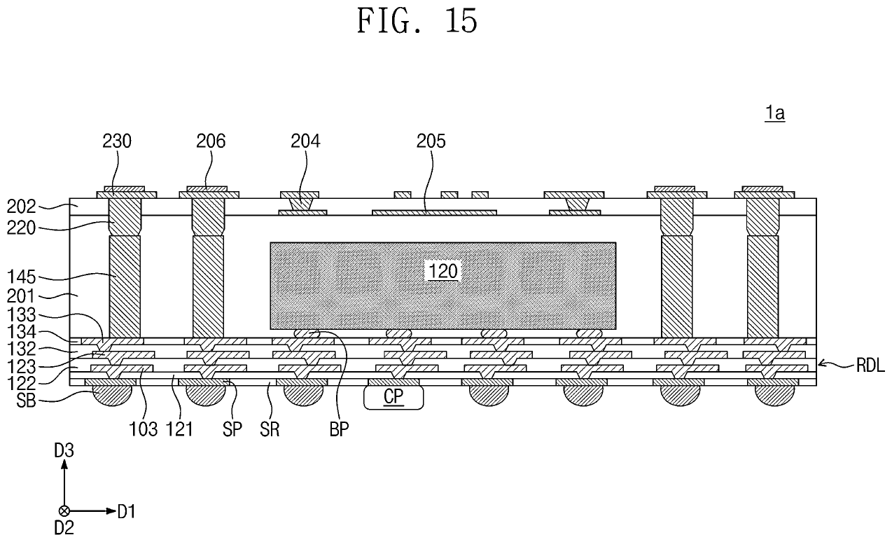

FIG. 15 is a sectional view illustrating a semiconductor package according to some embodiments of the inventive concepts of the present disclosures. For concise description, features, which are different from the semiconductor package of FIGS. 1 and 2, will be mainly described below.

Referring to FIG. 15, a semiconductor package 1a may include the solder ball SB, the passive device CP spaced apart from the solder ball SB, the solder pad SP on the solder ball SB, a solder insulating layer SR provided on the solder pad SP with the solder pad SP interposed therebetween, an additional insulating layer 121 on the solder insulating layer SR, the redistribution substrate RDL on the additional insulating layer 121, a connection structure 145 on the redistribution substrate RDL, the semiconductor chip 120 on the redistribution substrate RDL, the chip pad CPD on the semiconductor chip 120, the hybrid via 220 on the connection structure 145, the upper pad 230 on the hybrid via 220, the conductive pad 206 on the upper pad 230, the chip mold layer 201 on the redistribution substrate RDL, the interconnection pad 205 on the chip mold layer 201, the interconnection via 204 on the interconnection pad 205, and the capping mold layer 202 on the chip mold layer 201. The chip pad CPD may be between the semiconductor chip 120 and the redistribution substrate RDL.

The redistribution patterns 103, 123, and 133 may include the first redistribution pattern 103 on the solder pad SP, the second redistribution pattern 123 on the first redistribution pattern 103, and the third redistribution pattern 133 on the second redistribution pattern 123. In this case, each or at least one of the redistribution patterns 103, 123, and 133 may include an upper portion, which is extended in the first direction D1 (and/or the second direction D2), and a lower portion, which protrudes from the upper portion toward the solder pad SP.

The connection structure 145 of the semiconductor package 1a may have a substantially constant width (in the first direction D1 and/or the second direction D2). The connection structure 145 of the semiconductor package 1a may have, for example, a through-silicon via structure. The connection structure 145 may be electrically connected to the redistribution substrate RDL and the hybrid via 220.

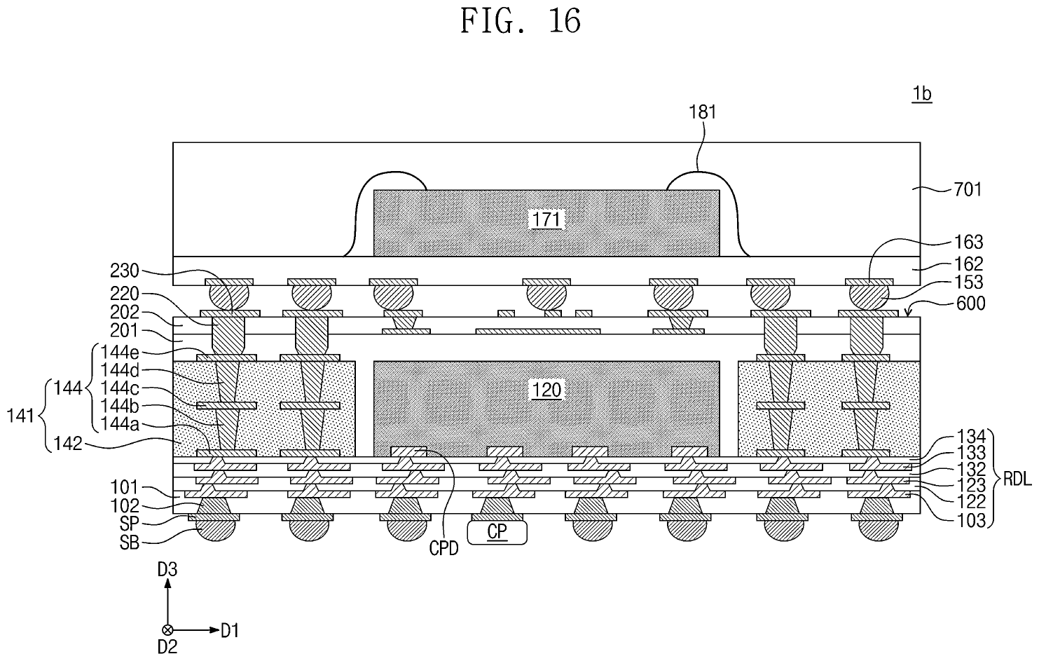

FIG. 16 is a sectional view illustrating a semiconductor package according to some embodiments of the inventive concepts of the present disclosures. For concise description, features, which are different from the semiconductor package of FIGS. 1 and 2, will be mainly described below.

Referring to FIG. 16, a memory package 1b may include a first semiconductor package 600, which has a similar structure to the semiconductor package 1 of FIG. 2, and a memory structure 171, which is provided on the first semiconductor package 600. A body substrate 162 may be provided between the first semiconductor package 600 and the memory structure 171, a body pad 163 may be disposed in the body substrate 162, and a pad solder 153 may be provided below the body pad 163.

The memory structure 171 may be (mounted) on the body substrate 162 and may be electrically connected to the body substrate 162 through a bonding wire 181. The body substrate 162 may be formed of or include, for example, silicon, glass, ceramic, and/or plastic materials. In some embodiments, the body substrate 162 may include an interconnection layer, which is provided therein and has a single- or multi-layered structure.

The body substrate 162 and the memory structure 171 may be electrically connected to each other through penetration vias (e.g., through-silicon vias) (not shown), semiconductor bumps (not shown), or chip pads (not shown).

A memory mold layer 701 may be provided on (e.g., to cover and/or to overlap) the memory structure 171, and thus, the memory structure 171 may be protected by the memory mold layer 701. The memory mold layer 701 may be on (e.g., cover and/or overlap) an upper surface of the body substrate 162 and the bonding wire 181. The memory mold layer 701 may be formed of or include, for example, silicon-based materials, thermosetting resins, thermoplastic resins, and/or UV-treatment materials.

In some embodiments, the first semiconductor package 600 may have substantially the same structure as the semiconductor package 1 of FIG. 2, from which the conductive pad 206 is removed, as shown in FIG. 16.

Although not shown, in some embodiments, the first semiconductor package 600 may have the same structure as the semiconductor package 1 of FIG. 2 including the conductive pad 206.

According to some embodiments of the inventive concept, a semiconductor package may include a hybrid via with an extended portion and an inclined portion. Since the hybrid via includes the inclined portion, it may be possible to improve a void issue in the via structure. Furthermore, since the hybrid via includes not only the inclined portion but also the extended portion, it may be easy to realize a fine circuit.

While example embodiments of the inventive concept have been particularly shown and described, it will be understood by one of ordinary skill in the art that variations in form and detail may be made therein without departing from the scope of the attached claims.

What is claimed is:

1. A semiconductor package, comprising:
a redistribution substrate that includes a redistribution pattern and a redistribution insulating layer;
a semiconductor chip on the redistribution substrate;
a connection structure that is spaced apart from the semiconductor chip; and
a hybrid via on the connection structure,
wherein the hybrid via comprises an inclined portion and an extended portion on the inclined portion, and
wherein an angle between the inclined portion and an upper surface of the connection structure ranges from 50° to 75°.

2. The semiconductor package of claim 1, further comprising:
a chip mold layer on the semiconductor chip and the connection structure; and
a capping mold layer on the chip mold layer,
wherein a side surface of the hybrid via is in contact with the chip mold layer and the capping mold layer.

3. The semiconductor package of claim 2, wherein the chip mold layer and the capping mold layer include a non-photoimageable material.

4. The semiconductor package of claim 1, wherein a width of the extended portion in a first direction is greater than a width of a lower surface of the inclined portion in the first direction, and
wherein the first direction is parallel with an upper surface of the redistribution substrate.

5. The semiconductor package of claim 1, wherein the connection structure further comprises:
a penetration connecting portion that electrically connects the hybrid via and the redistribution substrate; and
a connection mold layer,
wherein the penetration connecting portion extends into the connection mold layer,
wherein a width of an upper surface of the penetration connecting portion in a first direction is greater than a width of the extended portion in the first direction, and
wherein the first direction is parallel with an upper surface of the redistribution substrate.

6. The semiconductor package of claim 1, wherein a width of the inclined portion in a first direction decreases as a distance to the connection structure in a second direction decreases, and
wherein the first direction is parallel with an upper surface of the redistribution substrate, and the second direction is perpendicular to the upper surface of the redistribution substrate.

7. The semiconductor package of claim 1, further comprising:
an upper pad on the hybrid via, and
a conductive pad on the upper pad,
wherein the conductive pad comprises a plurality of conductive layers.

8. The semiconductor package of claim 1, wherein the extended portion of the hybrid via extends in a first direction that is perpendicular to an upper surface of the redistribution substrate.

9. The semiconductor package of claim 1, wherein the hybrid via comprises a hybrid via hole that at least partially includes a conductive material therein.

10. A semiconductor package, comprising:
a redistribution substrate that includes a redistribution pattern and a redistribution insulating layer;
a semiconductor chip on the redistribution substrate;
a connection structure that is spaced apart from the semiconductor chip; and
a hybrid via on the connection structure,
wherein the hybrid via comprises an inclined portion and an extended portion on the inclined portion,
wherein a width of the inclined portion in a first direction decreases as a distance to the connection structure in a second direction decreases, and
wherein the first direction is parallel with an upper surface of the redistribution substrate, and the second direction is perpendicular to the upper surface of the redistribution substrate.

11. The semiconductor package of claim 10, wherein an angle between the inclined portion and an upper surface of the connection structure ranges from 50° to 75°.

12. The semiconductor package of claim 10, wherein the connection structure further comprises:
a penetration connecting portion that electrically connects the hybrid via and the redistribution substrate; and
a connection mold layer,
wherein the penetration connecting portion extends into the connection mold layer, and
wherein a width of an upper surface of the penetration connecting portion in the first direction is greater than a width of the extended portion in the first direction.

13. The semiconductor package of claim 12, wherein the penetration connecting portion comprises:
a first connecting portion;
a second connecting portion on the first connecting portion; and
a third connecting portion on the second connecting portion,
wherein a width of an upper portion of the second connecting portion in the first direction is greater than a width of a lower portion of the second connecting portion in the first direction,
wherein a width of the first connecting portion in the first direction is greater than the width of the lower portion of the second connecting portion in the first direction, and
wherein an insulating material extends around the first connecting portion and the second connecting portion.

14. The semiconductor package of claim 10, further comprising an upper pad on the hybrid via,
wherein a width of the upper pad in the first direction is greater than a width of the extended portion of the hybrid via in the first direction, and
wherein the width of the extended portion of the hybrid via in the first direction is greater than a width of a lower surface of the inclined portion of the hybrid via in the first direction.

15. The semiconductor package of claim 14, further comprising a conductive pad on the upper pad,
wherein the conductive pad includes Ni and/or Au.

16. The semiconductor package of claim 14, further comprising:
a chip mold layer that extends around the semiconductor chip and the connection structure; and
a capping mold layer on the chip mold layer,
wherein the hybrid via extends into the capping mold layer and extends into the chip mold layer.

17. The semiconductor package of claim 16, wherein the capping mold layer includes a non-photoimageable material.

18. The semiconductor package of claim 10, wherein the connection structure further comprises:
a penetration connecting portion that electrically connects the hybrid via and the redistribution substrate; and
a connection mold layer,
wherein the penetration connecting portion extends into the connection mold layer, and
wherein a first angle between a side surface of the extended portion of the hybrid via and an upper surface of the penetration connecting portion is greater than a second angle between a side surface of the inclined portion of the hybrid via and the upper surface of the penetration connecting portion.

19. A semiconductor package, comprising:
a redistribution substrate that includes a redistribution pattern and a redistribution insulating layer;
a semiconductor chip on the redistribution substrate;
a connection structure that is spaced apart from the semiconductor chip;
a hybrid via on the connection structure;
a solder via on a lower surface of the redistribution substrate; and
a solder pad on a lower surface of the solder via,
wherein the hybrid via comprises an inclined portion and an extended portion on the inclined portion,
wherein the connection structure comprises a connection mold layer and a penetration connecting portion that is electrically connected to the redistribution pattern,
wherein the penetration connecting portion extends into the connection mold layer,
wherein the connection mold layer is spaced apart from the semiconductor chip,
wherein an angle between the inclined portion of the hybrid via and an upper surface of the penetration connecting portion ranges from 50° to 75°, and
wherein the solder pad, the solder via, the penetration connecting portion, and the hybrid via are electrically connected to each other.

20. The semiconductor package of claim 19, wherein a width of the inclined portion in a first direction decreases as a distance to the connection structure in a second direction decreases, and
wherein the first direction is parallel with an upper surface of the redistribution substrate, and the second direction is perpendicular to the upper surface of the redistribution substrate.
